(19) United States
(12) Patent Application Publication
(10) Pub. No.: US 2018/0189140 A1
(43) Pub. Date: Jul. 5, 2018

(54) ENHANCED ERROR CORRECTING MECHANISM TO PROVIDE RECOVERY FROM MULTIPLE ARBITRARY PARTITION FAILURE

(71) Applicant: Intel Corporation, Santa Clara, CA (US)

(72) Inventor: Ravi H. Motwani, San Diego, CA (US)

(21) Appl. No.: 15/396,525

(22) Filed: Dec. 31, 2016

(51) Int. Cl. G06F 11/10; H03M 13/11; H03M 13/00

(52) U.S. Cl. CPC G06F 11/1092; H03M 13/616; H03M 13/116; H03M 13/1177

(57) ABSTRACT

Embodiments are generally directed to an enhanced error correcting mechanism to provide recovery from multiple arbitrary partition failure. An embodiment of a memory device includes a memory controller; multiple memory dies, each memory die including at least two partitions; an error correction code (ECC) circuit block including an ECC encoder and an ECC decoder and corrector, wherein the ECC encoder is to encode data utilizing an LDPC (Low Density Parity Check) code having an H matrix, the LDPC code enabling a single step recovery from a failure of any of the memory dies; and a memory interface. Upon detection of a failure of a first partition of the plurality of memory dies at a first time, the ECC decoder and corrector is to recover data in the memory dies using the data encoded with the LDPC code based on the H matrix. The memory device is to generate a reduced H matrix to remove elements for the first failed partition, and the ECC encoder is to encode data utilizing the LDPC code based on the reduced H matrix.

### TECHNICAL FIELD

Embodiments described herein generally relate to the field of electronic devices and, more particularly, an enhanced error correcting mechanism to provide recovery from multiple arbitrary partition failure.

### BACKGROUND

In computer memory, ECC (Error Correction Code) enabled memory may be utilized to provide error correction, including circumstances in which a memory die or partition has failed. As memory devices are increased in memory capacity with many partitions, the possibility that there will be more than one memory die failure in single memory device has increased.

Reed-Solomon codes are non-binary cyclic error-correcting codes based on univariate polynomials over finite fields. A Reed-Solomon encoded memory can provide for multiple partition failure, but such protection is provided at the cost of increased data latency and reduced data throughput because of the overhead of such a system.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of a memory device providing recovery from failure of multiple arbitrary partitions of memory dies;

FIG. 2 is an illustration of a portion of an H matrix constructed to provide single step recoverability from failure of any die in the operation of a memory according to an embodiment;

FIG. 3 is an illustration of a process for modifying the data subsequent to a partition failure according to an embodiment;

FIG. 4 is an illustration of H matrices for a memory to recover from multiple arbitrary failed partitions according to an embodiment;

FIG. 5 is a flow chart to illustrate a process for recovery from multiple arbitrary partition failures according to an embodiment; and

FIG. 6 is an illustration of a system including memory to allow recovery from multiple arbitrary partition failure according to an embodiment.

### DETAILED DESCRIPTION

Embodiments described herein are generally directed to an enhanced error correcting mechanism to provide recovery from multiple arbitrary partition failure.

In computer memory, as memory element size has been scaled smaller, memory devices with increased memory capacity have been introduced, including the use of numerous memory dies with partitions within a memory device. However, with the increase in number of memory dies and partitions increases the likelihood that a particular memory device will have multiple partition failures.

LDPC (Low Density Parity Check) codes have been implemented to provide ECC (error correction code) operation for memory dies. LDPC code is a linear ECC that includes a parity check matrix (or H matrix) with sparse coding. Conventional LDPC codes may be implemented in computer memory having multiple memory dies to recover from a failure of any single die of the multiple memory dies. Min-sum (MS) decoding may be applied to LDPC encoded data.

However, as memory devices are increased in size with many die partitions, the possibility of multiple partition failures is increased, and a conventional LDPC mechanism for ECC memory will not provide for recovery from two arbitrary partition failures in different dies of a multi-die memory, as contrasted with the recovery from the failure of the partitions of a single memory die. Thus, the occurrence of two arbitrary partition failures generally results in the failure of an LDPC encoded memory device.

In some embodiments, an apparatus, system, or process provides an enhanced error correcting mechanism to provide recovery from multiple arbitrary partition failures. In some embodiments, an apparatus, system, or process includes an LDPC encoding that provides for recovery from a first partition failure at a first time and a second partition failure at a second time.

In some embodiments, an LDPC encoded apparatus or system including n memory partitions includes:

(a) LDPC encoding including entries in a circulant pattern to enable a single step recovery from any memory die failure; and

(b) A mechanism to reduce the H matrix to cover the remaining partitions after a loss of a first partition at a first time to enable recovery from the loss of any of the remaining partitions at a second time.

In operation, an embodiment of the LDPC encoded memory device with recovery from two arbitrary partitions can provide a significant improvement in raw bit error rate (RBER), such as a 2× RBER gain improvement, as compared to conventional Reed-Solomon codes, while permitting recovery from two arbitrary partition failures in addition to a single memory die failure. The LDPC encoded memory device also gives a latency advantage compared to the Reed-Solomon encoded device. For example, Table 1 provides a comparison between LDPC and Reed-Solomon with regard to data latency and throughput:

TABLE 1

| | Average | 99% | 99.999% | Maximum | |
|---|---|---|---|---|---|
| | Latency | Latency | Latency | Latency | Throughput |
| | (nsec) | (nsec) | (nsec) | (nsec) | (Mbps) |
| LDPC | 10.98 | 12 | 30 | 204 | 57.38 |
| Reed-Solomon | 56 | 98 | 178 | 290 | 11.25 |

Comparison of Data Latency LDPC Code vs. Reed Solomon Code

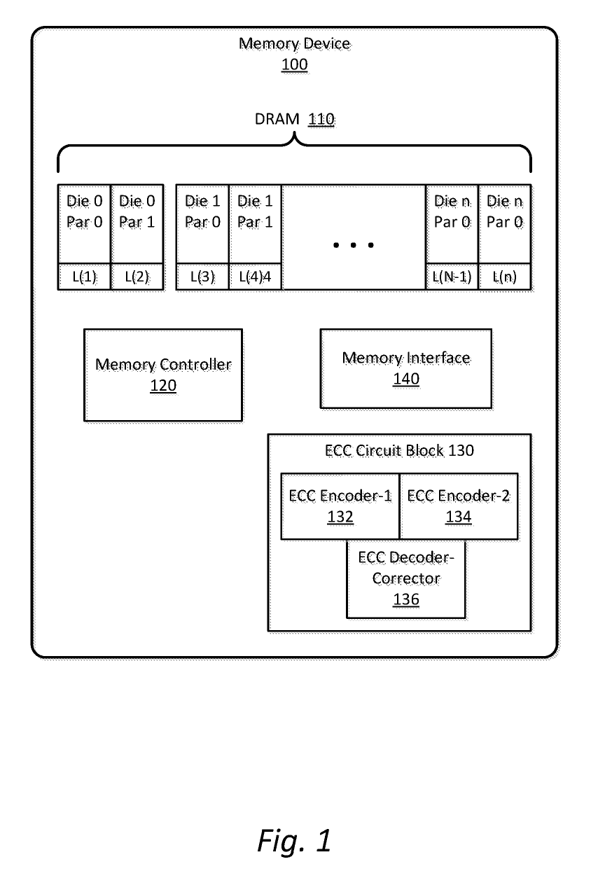

FIG. 1 is an illustration of a memory device providing recovery from failure of multiple arbitrary partitions of memory dies. As illustrated in FIG. 1, a memory device 100 includes DRAM (Dynamic Random Access Memory) 110 including multiple memory dies, including a total of n memory dies in the illustrated example, with each memory die including multiple partitions, including two partitions per memory die in the illustration. Thus, there are a total of n×2 partitions in the memory device.

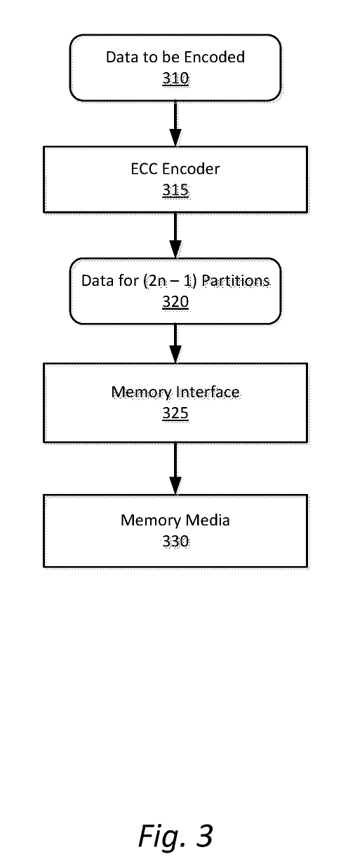

In some embodiments, the memory device 100 further includes a memory controller 120 to provide general control of the memory device 100. Memory device 100 may also include an ECC circuit block 130 including one or more ECC encoders and an ECC decoder-corrector For example, ECC circuit block 130 may include a first ECC encoder unit 132 to encode ECC data based on LDPC coding for the full (2×n) partitions and a second ECC encoder unit 134 to encode ECC data based on LDPC coding for a reduced (2×n−1) partitions. ECC circuit block 130 may also include an ECC decoder-corrector 136 to decode ECC data and correct if required. Memory device 100 may also include a memory interface 140 to interface between the ECC circuit block 130 and the DRAM 110. In some embodiments, the operation of the memory interface 140 and ECC encoder 132-134 may be as illustrated in FIG. 3 for a loss of a partition.

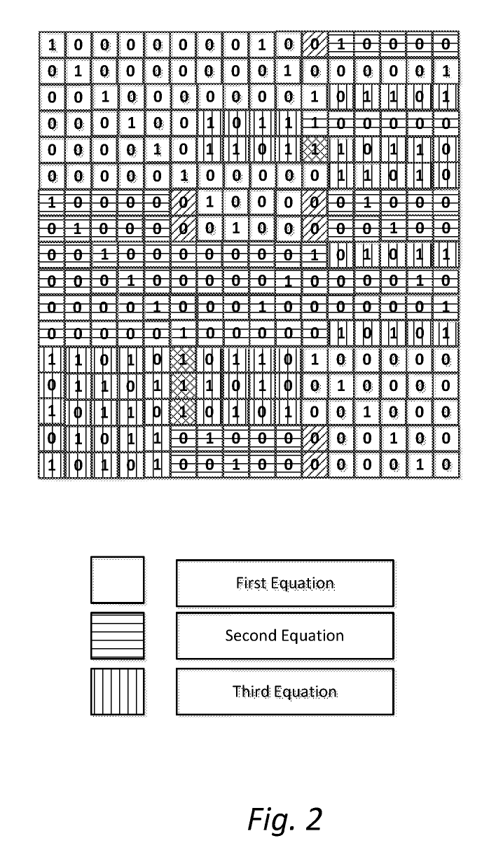

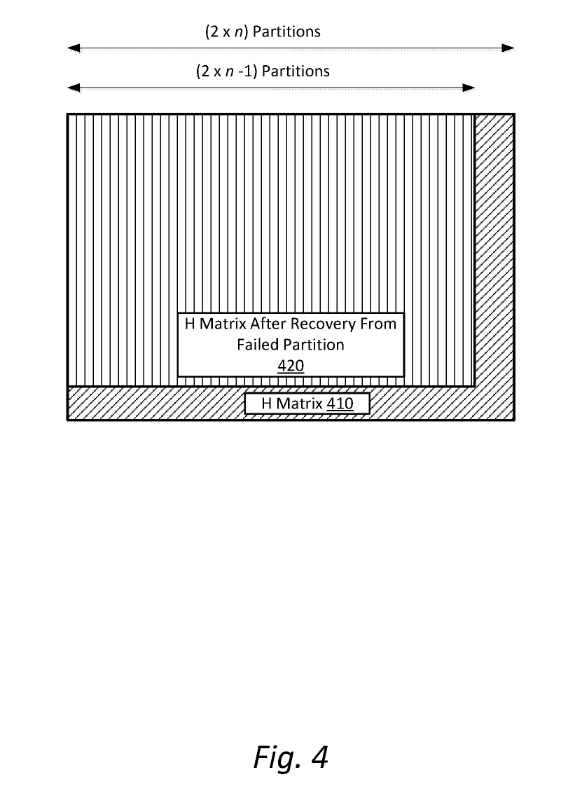

In some embodiments, the LDPC coding chosen for the memory device 100 is to enable a single step recovery from a memory die failure. In some embodiments, the H matrix for a memory device is structured as illustrated in FIG. 2. In some embodiments, the modification of an H matrix for the loss of a partition is as illustrated in FIG. 4.

In some embodiments, the memory interface 140 is operable to address the reduced number of partitions resulting from the loss of a first partition at a first time. In some embodiments, the interface is operable to avoid writing data to the failed partition. In an alternative embodiment, the ECC encoder may instead be informed about the failed partition, with the generated ECC data including dummy bits for the failed partition.

FIG. 2 is an illustration of a portion of an H matrix constructed to provide single step recoverability from a memory die failure in the operation of a memory according to an embodiment. In some embodiments, because the code is required to recover for memory die failure, the LDPC code is chosen to ensure single step recoverability from a memory die failure regardless of which memory die fails. In this illustration, it is assumed that the memory device contains 20 memory dies, with each memory die including 2 partitions, for a total of 40 partitions.

Each entry in the illustrated H matrix portion is a circulant permutation matrix, the encoding being specifically a quasi-cyclic LDPC (QC-LDPC) code based on circulant permutation matrices. In the H matrix, a ‘0’ indicates that the circulant is masked and a ‘1’ indicates that the circulant is not masked.

In a particular implementation, there is an ECC code that is spread across a plurality of dies, such as in an example 20 dies. In this example, there are 32 bytes in a die in two partitions, 16 bytes in each of the 40 partitions. If there is a memory die failure, the ECC code can handle and correct the data loss.

In this illustration, each column includes 48 bits. Dividing the number of bits by the number of bits in each column 256/48=5.33. In this example, a memory die failure results in 5.33 circulants being lost, wherein the loss may be in the first 5.33 circulants. FIG. 2 illustrates elements of a first equation, a second equation, and a third equation in the H matrix, where other cells may be shared between memory dies. In the H matrix, the first equation and the second equation present 6×6 identity portions in the H matrix (as illustrated in the first twelve lines and six columns of the H matrix), and these portions permit solving the bits lost by the memory die failure because there is only one erased bit in the rows corresponding to the first 6 elements of the first equation and the second equation. Thus, in one step, the lost bits from a failed memory die can be reconstructed, with errors. The min-sum decoding of the LDPC decoding can then correct the errors only scenario and perform the decoding process.

However, the construction for memory die failure is not sufficient alone to recover from two arbitrary partition failures. In some embodiments, an apparatus, system, and process provides for recovery from two arbitrary partition failures, wherein a first failure occurs at a first time and the second partition occurs at a second time. In some embodiments, the information from the first partition failure is utilized to update the code information, and thus enable recovery from the second partition failure.

FIG. 3 is an illustration of a process for modifying the data subsequent to a partition failure according to an embodiment. In this illustration, data to be encoded 310 is received at the ECC encoder 315. However, if a partition of the (2×n) partitions (such as one of the 40 partitions in the example of 20 memory dies of two partitions each) has been lost, there then is data for the remaining (2×n−1) partitions 320 (39 partitions in the particular example). In some embodiments, the memory interface 325 receives the data, with the interface being notified of the failed partition and, in response to the notification of the failed partition, the interface is to convert the data to the full (2×n) partitions (40 partitions) with dummy data for the failed partition, and then performing the write to the memory media 330.

In some embodiments, alternatively the ECC encoder 315 is also informed regarding the location of the failed partition, the ECC encoder to insert dummy bits into the data and provide data for the full (2×n) partitions (40 partitions).

FIG. 4 is an illustration of H matrices for a memory to recover from multiple arbitrary failed partitions according to an embodiment. In some embodiments, a memory unit initially operates with a full H matrix 410 to provide encoding for the full (2×n) partitions (i.e., 40 partitions for an example memory unit with 20 dies and 2 partitions per die). Upon the failure of a first partition at a first time, resulting in operation with (2×n−1) partitions, the memory unit is to switch to an H matrix 420 corresponding to the (2×n−1) partitions (39 remaining partitions in the example).

In some embodiments, the decoder is not altered as the memory can utilize zeros for the last circulant. However, the encoding of the data is changed to encode for the reduced number of partitions. Thus, the hardware complexity increase in an embodiment is limited to a second encoder, without requiring additional decoding costs.

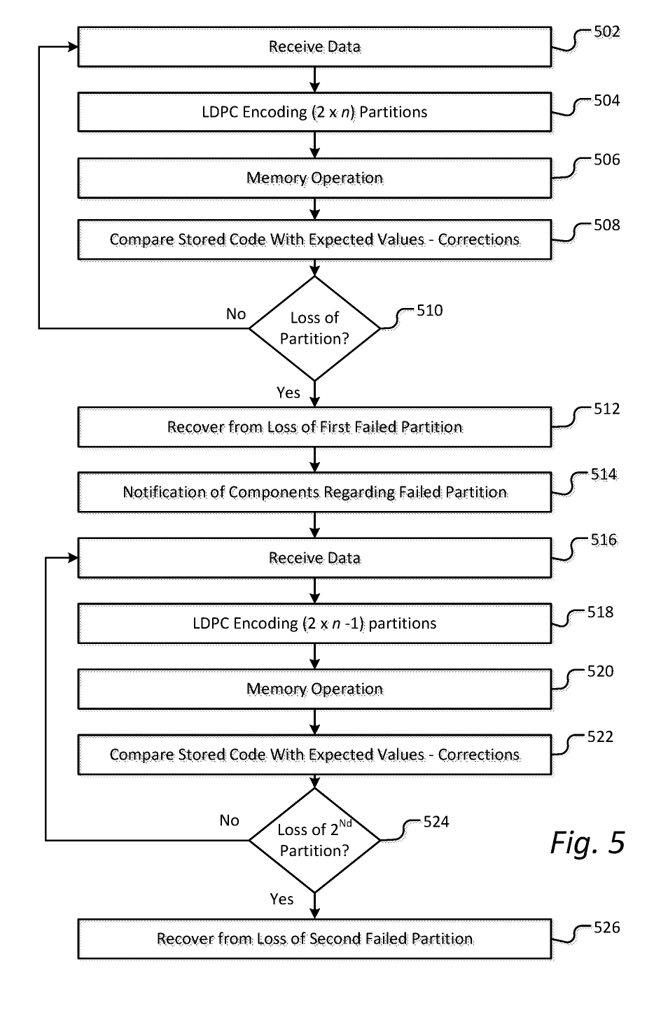

FIG. 5 is a flow chart to illustrate a process for recovery from multiple arbitrary partition failures according to an embodiment. In some embodiments, a process may include:

502: Receiving data for storing in a memory device.

504: ECC operation to provide LDPC encoding of each partition of the memory, or (2×n) partitions for a memory device including n memory dies and 2 partitions per memory die. More specifically, the encoding is a quasi-cyclic LDPC (QC-LDPC) code based on circulant permutation matrices.

506: Providing a memory operation pursuant to instruction.

508: For the memory operation, comparing the stored code with expected values to identify errors, and providing correction of errors utilizing the ECC data.

510: If there is a failure of a first partition in the memory device at a first time, the normal process is interrupted for recovery.

512: Recovering from the loss of a first partition, wherein the LDPC encoding is sufficient to provide recovery of the data in the failure of any partition of the full set of (2×n) partitions.

514: Notification of components regarding the failed partition for operation with reduced partitions, which may include switching to a second ECC encoder for data encoding and switching operation of a memory interface for the loss of the failed partition.

516: The process may then continue with receiving data for storing in the memory device.

518: ECC operation to provide LDPC encoding of each remaining partition of memory, or (2×n−1) partitions for the device after the loss of one failed partition. For example, the H matrix may be reduced as illustrated in FIG. 4.

520: Providing a memory operation pursuant to instruction.

522: For the memory operation, comparing the stored code with expected values to identify errors, and providing correction of errors utilizing the ECC data.

524: If there is a failure of a second partition in the memory device at a second time, the normal process is interrupted for recovery.

526: Recovering from the loss of the second partition, the LDPC encoding enabling recovery of the data for the failure of any partitions of the remaining (2×n−1) partitions.

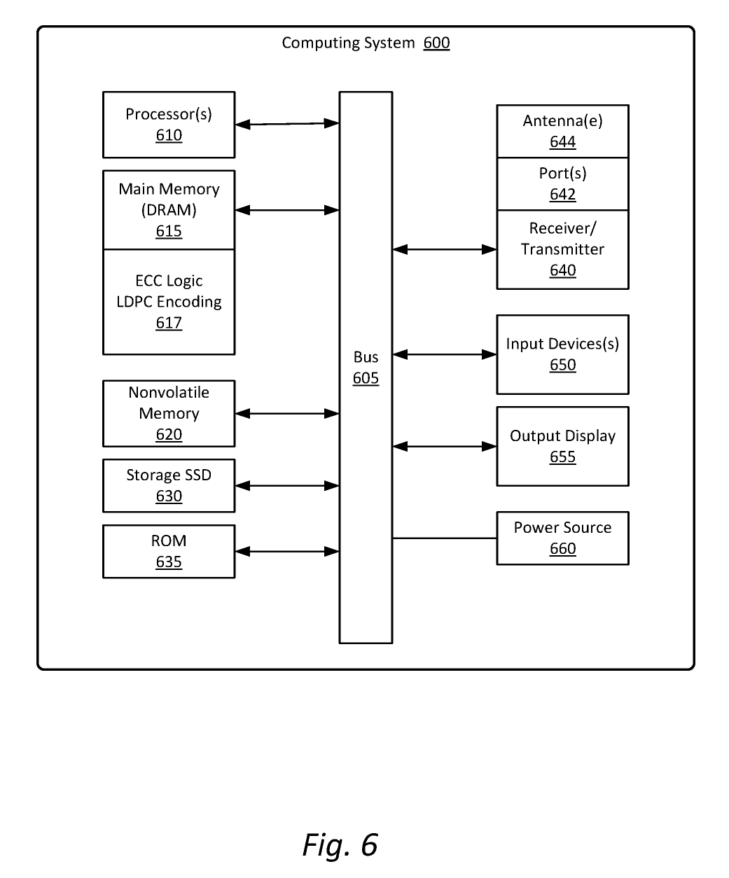

FIG. 6 is an illustration of a system including memory to allow recovery from multiple arbitrary partition failures according to an embodiment. In this illustration, certain standard and well-known components that are not germane to the present description are not shown. Elements shown as separate elements may be combined, including, for example, an SoC (System on Chip) combining multiple elements on a single chip.

In some embodiments, a computing system 600 may include a processing means such as one or more processors 610 coupled to one or more buses or interconnects, shown in general as bus 605. The processors 610 may comprise one or more physical processors and one or more logical processors. In some embodiments, the processors may include one or more general-purpose processors or special-purpose processors.

The bus 605 is a communication means for transmission of data. The bus 605 is illustrated as a single bus for simplicity, but may represent multiple different interconnects or buses and the component connections to such interconnects or buses may vary. The bus 605 shown in FIG. 6 is an abstraction that represents any one or more separate physical buses, point-to-point connections, or both connected by appropriate bridges, adapters, or controllers.

In some embodiments, the computing system 600 further comprises a random access memory (RAM) or other dynamic storage device or element as a main memory 615 for storing information and instructions to be executed by the processors 610. Main memory 615 may include, but is not limited to, dynamic random access memory (DRAM). In some embodiments, the main memory 615 includes one or more memory devices having multiple memory dies, including stacked memory, the memory dies including multiple partitions. In some embodiments, a memory device includes ECC circuit logic 617 to provide LDPC encoding of the partitions, wherein the ECC circuit logic 617 includes an LDPC encoding that enables single step recovery from the loss of a memory die; and further includes a mechanism to reduce the applicable H matrix to cover the remaining partitions to enable recovery from the loss of any of the remaining partitions at a second time.

The computing system 600 also may comprise a non-volatile memory 620; a storage device such as a solid-state drive (SSD) 630; and a read only memory (ROM) 635 or other static storage device for storing static information and instructions for the processors 610.

In some embodiments, the computing system 600 includes one or more transmitters or receivers 640 coupled to the bus 605. In some embodiments, the computing system 600 may include one or more antennae 644, such as dipole or monopole antennae, for the transmission and reception of data via wireless communication using a wireless transmitter, receiver, or both, and one or more ports 642 for the transmission and reception of data via wired communications. Wireless communication includes, but is not limited to, Wi-Fi, Bluetooth™, near field communication, and other wireless communication standards.

In some embodiments, computing system 600 includes one or more input devices 650 for the input of data, including hard and soft buttons, a joy stick, a mouse or other pointing device, a keyboard, voice command system, or gesture recognition system.

In some embodiments, computing system 600 includes an output display 655, where the output display 655 may include a liquid crystal display (LCD) or any other display technology, for displaying information or content to a user. In some environments, the output display 655 may include a touch-screen that is also utilized as at least a part of an input device 650. Output display 655 may further include audio output, including one or more speakers, audio output jacks, or other audio, and other output to the user.

The computing system 600 may also comprise a battery or other power source 660, which may include a solar cell, a fuel cell, a charged capacitor, near field inductive coupling, or other system or device for providing or generating power in the computing system 600. The power provided by the power source 660 may be distributed as required to elements of the computing system 600.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, read-only memory (ROM), random access memory (RAM), erasable programmable read-only memory (EPROM), electrically-erasable programmable read-only memory (EEPROM), magnetic or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, a memory device includes a memory controller; a plurality of memory dies, each memory die including at least two partitions; an error correction code (ECC) circuit block including an ECC encoder and an ECC decoder and corrector, wherein the ECC encoder is to encode data utilizing an LDPC (Low Density Parity Check) code having an H matrix, the LDPC code enabling a single step recovery from a failure of any of the plurality of memory dies; and a memory interface. In some embodiments, upon detection of a failure of a first partition of the plurality of memory dies at a first time, the ECC decoder and corrector is to recover data in the plurality of memory dies using the data encoded with the LDPC code based on the H matrix; and the memory device is to generate a reduced H matrix to remove elements for the first failed partition, the ECC encoder to encode data utilizing the LDPC code based on the reduced H matrix.

In some embodiments, upon detection of a failure of a second partition of the plurality of memory dies at a second time, the ECC decoder and corrector is to recover data in the plurality of memory dies using the data encoded with the LDPC code based on the reduced H matrix.

In some embodiments, the LDPC code is a quasi-cyclic LDPC (QC-LDPC) code.

In some embodiments, the memory interface is operable to convert data for storage in the remaining partitions of the plurality of memory dies without the first partition.

In some embodiments, the first partition and second partitions are any of the partitions of the plurality of memory dies.

In some embodiments, the ECC encoder circuit block includes a first encoder for encoding data for all of the partitions of the plurality of memory dies and a second encoder for encoding data for remaining partitions after failure of the first partition.

In some embodiments, the plurality of memory dies includes twenty memory dies, each of the twenty memory dies having two partitions.

In some embodiments, a method includes receiving a first data for a memory, the memory including a plurality of memory dies, each memory die including at least two partitions; encoding the first data for storage in the partitions of the memory according to an LDPC (Low Density Parity Check) code having an H matrix, the LDPC code enabling a single step recovery from a failure of any of the plurality of memory dies; detecting a failure of a first partition of the plurality of partitions at a first time; recovering the first data using data from remaining partitions of the memory without the first partition using the LDPC code based on the H matrix; generating a reduced H matrix to remove elements for the first failed partition; and encoding a second data for storage in the remaining partitions of the memory without the first and second partitions using the LDPC matrix based on the reduced H matrix.

In some embodiments, the method further includes detecting a failure of a second partition of the plurality of partitions at a second time; recovering the second data using data from remaining partitions of the plurality of memory dies using the LDPC code based on the reduced H matrix.

In some embodiments, the LDPC code is a quasi-cyclic LDPC (QC-LDPC) code.

In some embodiments, the method further including converting data for storage in the remaining partitions without the first partition.

In some embodiments, the first partition and second partitions are any of the partitions of the plurality of memory dies.

In some embodiments, the plurality of memory dies includes twenty memory dies, each of the twenty memory dies having two partitions.

In some embodiments, a system includes one or more processors for processing of data; and a memory for storage of data for the processor, the memory including a first memory device. In some embodiments, the first memory device includes a memory controller; a plurality of memory dies, each die including at least two partitions; an error correction code (ECC) circuit block including an ECC encoder and an ECC decoder and corrector, wherein the ECC encoder is to encode data utilizing an LDPC (Low Density Parity Check) code having an H matrix, the LDPC code enabling a single step recovery from a failure of any of the plurality of memory dies; and a memory interface. In some embodiments, upon detection of a failure of a first partition of the plurality of memory dies at a first time, the ECC decoder and corrector is to recover data in the plurality of memory dies using the data encoded with the LDPC code based on the H matrix; and the first memory device is to generate a reduced H matrix to remove elements for the first failed partition, the ECC encoder to encode data utilizing the LDPC code based on the reduced H matrix.

In some embodiments, upon detecting a failure of a second partition of the plurality of memory dies at a second time, the ECC decoder and corrector is to recover data in the plurality of memory dies using the data encoded with the LDPC code based on the reduced H matrix.

In some embodiments, the LDPC code is a quasi-cyclic LDPC (QC-LDPC) code.

In some embodiments, the memory interface is operable to convert data for storage in the remaining partitions of the plurality of memory dies without the first partition.

In some embodiments, the first partition and second partitions are any of the partitions of the plurality of memory dies.

In some embodiments, the ECC encoder includes a first encoder for encoding data for all of the partitions of the plurality of memory dies and a second encoder for encoding data for remaining partitions after failure of the first partition.

In some embodiments, the plurality of memory dies includes twenty memory dies, each of the twenty memory dies having two partitions.

In some embodiments, the system further includes a transmitter or receiver for transmission or reception of data; and a dipole antenna for the transmission or reception of data;

In some embodiments, a non-transitory computer-readable storage medium having stored thereon data representing sequences of instructions that, when executed by a processor, cause the processor to perform operations including receiving a first data for a memory, the memory including a plurality of memory dies, each memory die including at least two partitions; encoding the first data for storage in the partitions of the memory according to an LDPC (Low Density Parity Check) code having an H matrix, the LDPC code enabling a single step recovery from a failure of any of the plurality of memory dies; detecting a failure of a first partition of the plurality of partitions at a first time; recovering the first data using data from remaining partitions of the memory without the first partition using the LDPC code based on the H matrix; generating a reduced H matrix to remove elements for the first failed partition; and encoding a second data for storage in the remaining partitions of the memory without the first and second partitions using the LDPC matrix based on the reduced H matrix.

In some embodiments, the medium further includes instructions for detecting a failure of a second partition of the plurality of partitions at a second time; and recovering the second data using data from remaining partitions of the plurality of memory dies using the LDPC code based on the reduced H matrix.

In some embodiments, the LDPC code is a quasi-cyclic LDPC (QC-LDPC) code.

In some embodiments, the medium further includes instructions for converting data for storage in the remaining partitions without the first partition.

In some embodiments, the first partition and second partitions are any of the partitions of the plurality of memory dies.

In some embodiments, an apparatus includes means for receiving a first data for a memory, the memory including a plurality of memory dies, each memory die including at least two partitions; means for encoding the first data for storage in the partitions of the memory according to an LDPC (Low Density Parity Check) code having an H matrix, the LDPC code enabling a single step recovery from a failure of any of the plurality of memory dies; means for detecting a failure of a first partition of the plurality of partitions at a first time; means for recovering the first data using data from remaining partitions of the memory without the first partition using the LDPC code based on the H matrix; means for generating a reduced H matrix to remove elements for the first failed partition; and means for encoding a second data for storage in the remaining partitions of the memory without the first and second partitions using the LDPC matrix based on the reduced H matrix.

In some embodiments, the apparatus further includes means for detecting a failure of a second partition of the plurality of partitions at a second time; and means for recovering the second data using data from remaining partitions of the plurality of memory dies using the LDPC code based on the reduced H matrix.

In some embodiments, the LDPC code is a quasi-cyclic LDPC (QC-LDPC) code.

In some embodiments, the apparatus further includes means for converting data for storage in the remaining partitions without the first partition.

In some embodiments, the first partition and second partitions are any of the partitions of the plurality of memory dies.

What is claimed is:

1. A memory device comprising:
a memory controller;
a plurality of memory dies, each memory die including at least two partitions;
an error correction code (ECC) circuit block including an ECC encoder and an ECC decoder and corrector, wherein the ECC encoder is to encode data utilizing an LDPC (Low Density Parity Check) code having an H matrix, the LDPC code enabling a single step recovery from a failure of any of the plurality of memory dies; and
a memory interface;
wherein, upon detection of a failure of a first partition of the plurality of memory dies at a first time, the ECC decoder and corrector is to recover data in the plurality of memory dies using the data encoded with the LDPC code based on the H matrix; and
the memory device is to generate a reduced H matrix to remove elements for the first failed partition, the ECC encoder to encode data utilizing the LDPC code based on the reduced H matrix.

2. The device of claim 1, wherein, upon detection of a failure of a second partition of the plurality of memory dies at a second time, the ECC decoder and corrector is to recover data in the plurality of memory dies using the data encoded with the LDPC code based on the reduced H matrix.

3. The device of claim 1, wherein the LDPC code is a quasi-cyclic LDPC (QC-LDPC) code.

4. The device of claim 1, wherein the memory interface is operable to convert data for storage in the remaining partitions of the plurality of memory dies without the first partition.

5. The device of claim 1, wherein the first partition and second partitions are any of the partitions of the plurality of memory dies.

6. The device of claim 1, wherein the ECC encoder circuit block includes a first encoder for encoding data for all of the partitions of the plurality of memory dies and a second encoder for encoding data for remaining partitions after failure of the first partition.

7. The device of claim 1, wherein the plurality of memory dies includes twenty memory dies, each of the twenty memory dies having two partitions.

8. A method comprising:
receiving a first data for a memory, the memory including a plurality of memory dies, each memory die including at least two partitions;
encoding the first data for storage in the partitions of the memory according to an LDPC (Low Density Parity Check) code having an H matrix, the LDPC code enabling a single step recovery from a failure of any of the plurality of memory dies;
detecting a failure of a first partition of the plurality of partitions at a first time;
recovering the first data using data from remaining partitions of the memory without the first partition using the LDPC code based on the H matrix;
generating a reduced H matrix to remove elements for the first failed partition; and
encoding a second data for storage in the remaining partitions of the memory without the first and second partitions using the LDPC matrix based on the reduced H matrix.

9. The method of claim 8, further comprising:
detecting a failure of a second partition of the plurality of partitions at a second time; and
recovering the second data using data from remaining partitions of the plurality of memory dies using the LDPC code based on the reduced H matrix.

10. The method of claim 8, wherein the LDPC code is a quasi-cyclic LDPC (QC-LDPC) code.

11. The method of claim 8, further comprising converting data for storage in the remaining partitions without the first partition.

12. The method of claim 8, wherein the first partition and second partitions are any of the partitions of the plurality of memory dies.

13. The method of claim 8, wherein the plurality of memory dies includes twenty memory dies, each of the twenty memory dies having two partitions.

14. A system comprising:
one or more processors for processing of data; and
a memory for storage of data for the processor, the memory including a first memory device;
wherein the first memory device includes:
a memory controller;
a plurality of memory dies, each memory die including at least two partitions;
an error correction code (ECC) circuit block including an encoder and an ECC decoder and corrector, wherein the ECC encoder is to encode data utilizing an LDPC (Low Density Parity Check) code having an H matrix, the LDPC code enabling a single step recovery from a failure of any of the plurality of memory dies; and
a memory interface;
wherein, upon detection of a failure of a first partition of the plurality of memory dies at a first time, the ECC decoder and corrector is to recover data in the plurality of memory dies using the data encoded with the LDPC code based on the H matrix; and
the first memory device is to generate a reduced H matrix to remove elements for the first failed partition, the ECC encoder to encode data utilizing the LDPC code based on the reduced H matrix.

15. The system of claim 14, wherein, upon detecting a failure of a second partition of the plurality of memory dies at a second time, the ECC decoder and corrector is to recover data in the plurality of memory dies using the data encoded with the LDPC code based on the reduced H matrix.

16. The system of claim 14, wherein the LDPC code is a quasi-cyclic LDPC (QC-LDPC) code.

17. The system of claim 14, wherein the memory interface is operable to convert data for storage in the remaining partitions of the plurality of memory dies without the first partition.

18. The system of claim 14, wherein the first partition and second partitions are any of the partitions of the plurality of memory dies.

19. The system of claim 14, wherein the ECC encoder includes a first encoder for encoding data for all of the partitions of the plurality of memory dies and a second encoder for encoding data for remaining partitions after failure of the first partition.

20. The system of claim 14, wherein the plurality of memory dies includes twenty memory dies, each of the twenty memory dies having two partitions.

21. The system of claim 14, further comprising a transmitter or receiver for transmission or reception of data; and a dipole antenna for the transmission or reception of data;

22. A non-transitory computer-readable storage medium having stored thereon data representing sequences of instructions that, when executed by a processor, cause the processor to perform operations comprising:
receiving a first data for a memory, the memory including a plurality of memory dies, each memory die including at least two partitions;
encoding the first data for storage in the partitions of the memory according to an LDPC (Low Density Parity Check) code having an H matrix, the LDPC code enabling a single step recovery from a failure of any of the plurality of memory dies;
detecting a failure of a first partition of the plurality of partitions at a first time;
recovering the first data using data from remaining partitions of the memory without the first partition using the LDPC code based on the H matrix;
generating a reduced H matrix to remove elements for the first failed partition; and
encoding a second data for storage in the remaining partitions of the memory without the first and second partitions using the LDPC matrix based on the reduced H matrix.

23. The medium of claim 22, further comprising instructions that, when executed by the processor, cause the processor to perform operations comprising:
detecting a failure of a second partition of the plurality of partitions at a second time; and
recovering the second data using data from remaining partitions of the plurality of memory dies using the LDPC code based on the reduced H matrix.

24. The medium of claim 22, wherein the LDPC code is a quasi-cyclic LDPC (QC-LDPC) code.

25. The medium of claim 22, further comprising further comprising instructions that, when executed by the processor, cause the processor to perform operations comprising:
converting data for storage in the remaining partitions without the first partition.

26. The medium of claim 22, wherein the first partition and second partitions are any of the partitions of the plurality of memory dies.
